(19) United States
(12) Patent Application Publication
(10) Pub. No.: US 2014/0177141 A1
(43) Pub. Date: Jun. 26, 2014

(54) FIXING STRUCTURE FOR BATTERY MODULE AND ELECTRONIC DEVICE WITH FIXING STRUCTURE

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: YAN-BANG CAO, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/851,718

(22) Filed: Mar. 27, 2013

(30) Foreign Application Priority Data
Dec. 22, 2012 (CN) 201210561647.2

(51) Int. Cl. H05K 7/00

(52) U.S. Cl. CPC H05K 7/00
USPC 361/679.01

(57) ABSTRACT

A fixing structure used to fix a battery module to a housing is provided. The fixing structure includes tape. A top surface of the tape is covered by at least one first double-sided adhesive tape. A lower surface of the tape is covered by at least one second double-sided adhesive tape. The at least one first double-sided adhesive tape is used to adhere the battery module to the top surface of the tape. The at least one second double-sided adhesive tape is used to adhere the lower surface of the tape to the housing. The adhesiveness of the first double-sided adhesive tape is less than that of the second double-sided adhesive tape.

### BACKGROUND

1. Technical Field

The present disclosure relates to electronic devices and, particularly, to an electronic device with a fixing structure for a battery module.

2. Description of Related Art

Battery modules are usually directly adhered to a housing of an electronic device such as tablet computer, using a highly adhesive double-sided tape. When the battery module needs to be examined or replaced, a prying device is needed to pry the battery module from the bottom. However, it is easy to damage the battery module by prying the battery module from the housing.

Therefore, what is need is a fixing structure to overcome the described limitations.

### BRIEF DESCRIPTION OF THE DRAWINGS

FIG. 1 is an isometric view of an electronic device in accordance with an exemplary embodiment.

FIG. 2 is an exploded view of the electronic device of FIG. 1.

### DETAILED DESCRIPTION

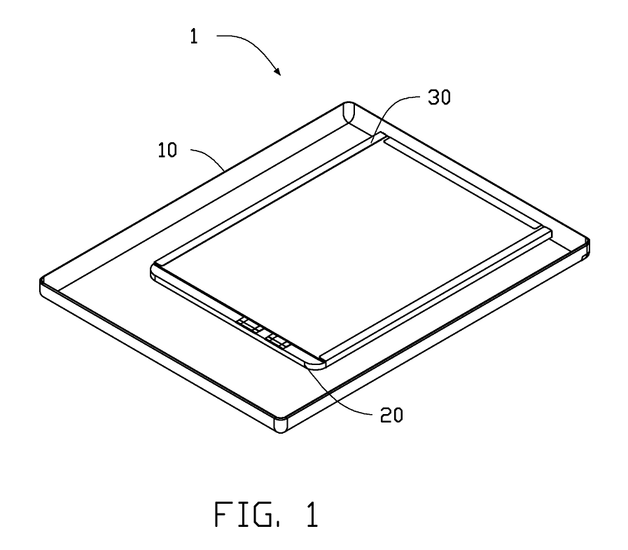

FIG. 1 shows an electronic device 1 in an exemplary embodiment. The electronic device 1 includes a housing 10 and a fixing structure 30 adhered to housing 10. In one embodiment, the electronic device 1 is a tablet computer.

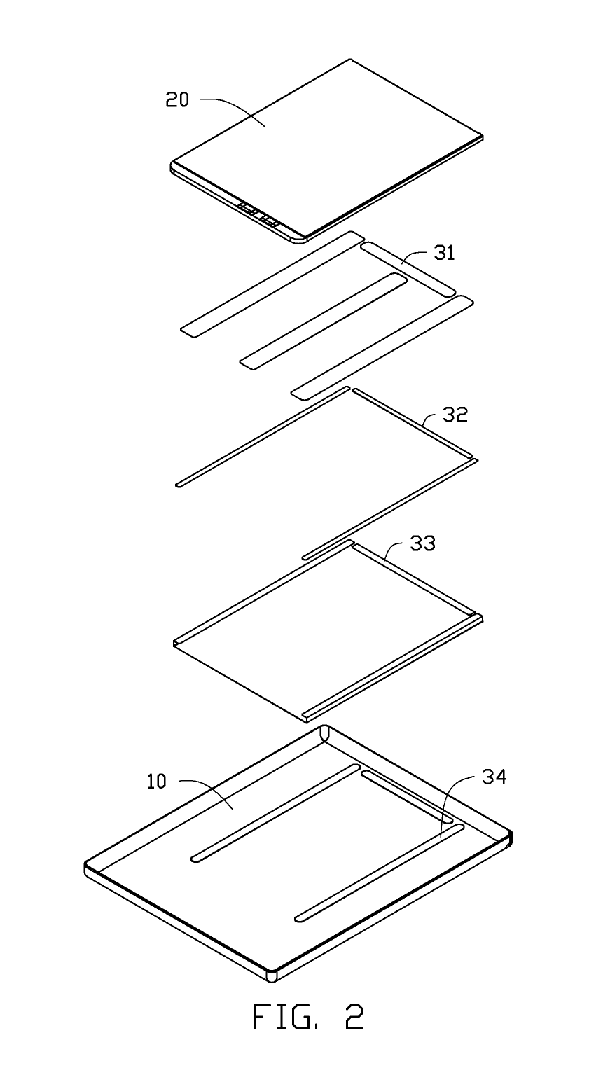

FIG. 2 shows that the fixing structure 30 includes tape 33. A top surface of the tape 33 is covered by at least one first double-sided adhesive tape 31. A lower surface of the tape 33 is covered by at least one second double-sided adhesive tape 34. The adhesiveness of the first double-sided adhesive tape 31 is less than the adhesiveness of the second double-sided adhesive tape 34. In one embodiment, the tape 33 is made of a foldable material. The first double-sided adhesive tape 31 is used to adhere a battery module 20 to the top surface of the tape 33. The second double-sided adhesive tape 34 is used to adhere the lower surface of the tape 33 to the housing 10, thus resulting in the battery module 20 being adhered to the housing 10 by the tape 33. When the user examines or replaces the housing 10, the battery module 20 only needs to be removed from the tape 33, because the adhesiveness of the first double-sided adhesive tape 31 is not strong, the battery module 20 is easily removed from the tape 33. In one embodiment, the first double-sided adhesive tape 31 and the second double-sided adhesive tape 34 are double-sided pressure-sensitive adhesive tape.

In one embodiment, the number of the at least one first double-sided adhesive tape 31 is four, the four first double-sided adhesive tapes 31 uniformly adhere the bottom of the battery module 20 to the tape 33.

In one embodiment, the number of the at least one second double-sided adhesive tape 34 is three, the three second double-sided adhesive tapes 34 uniformly adhere the bottom of the tape 33 to the housing 10.

Three sides of the tape 33 is covered by three third double-sided adhesive tapes 32. The three sides of the tape 33 is forced by an external force to fold to cover with three sidewalls of the battery module 20, the three third double-sided adhesive tapes 32 adhere the three folded sides of the tape 33 to the three sidewalls of the battery module 20, thereby preventing the battery module 20 from being disengaged from the tape 33 during a movement of the electronic device 1. The third double-sided adhesive tape 32 is a double-sided pressure-sensitive adhesive tape. In one embodiment, the adhesiveness of the third double-sided adhesive tape 32 is equal to the adhesiveness of the second double-sided adhesive tape 34. In other embodiments, the adhesiveness of the third double-sided adhesive tape 32 can also be different from the adhesiveness of the second double-sided adhesive tape 34.

When the user examines or replaces the housing 10, the third double-sided adhesive tape 32 is removed from the battery module 20, and the battery module 20 is removed from the tape 33. After examining operation or replacing operation for the housing 10 is finished, a new tape 33 can be adhered to the housing 10, the battery module 20 is adhered to the new tape 33, thereby reducing damage to the battery module 20 generated by removing the battery module 20 from the housing 10. Because the cost of the tape 33 is less than the cost of the battery module 20, it is cost effective.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A fixing structure used to fix a battery module to a housing comprising:
a tape;
wherein a top surface of the tape is covered by at least one first double-sided adhesive tape, a lower surface of the tape is covered by at least one second double-sided adhesive tape, the at least one first double-sided adhesive tape is used to adhere the battery module to the top surface of the tape, and the at least one second double-sided adhesive tape is used to adhere the lower surface of the tape to the housing, the adhesiveness of the first double-sided adhesive tape is less than the adhesiveness of the second double-sided adhesive tape.

2. The fixing structure as described in claim 1, wherein the number of the at least one first double-sided adhesive tape is four, and the four first double-sided adhesive tapes uniformly adhere the bottom of the battery module to the top surface of the tape.

3. The fixing structure as described in claim 1, wherein the number of the at least one second double-sided adhesive tape is three, and the three second double-sided adhesive tapes uniformly adhere the bottom of the tape to the housing.

4. The fixing structure as described in claim 1, wherein three sides of the tape are covered by three third double-sided adhesive tapes, three sidewalls of the battery module are covered by the three sides of the tape, the three third double-sided adhesive tapes adhere the three sides of the tape to the three sidewalls of the battery module.

5. The fixing structure as described in claim 4, wherein the first double-sided adhesive tape, the second double-sided adhesive tape and the third double-sided adhesive tape are double-sided pressure-sensitive adhesive tape.

6. An electronic device comprising:
a housing; and
a fixing structure as described in claim 1, wherein the fixing structure is adhered to the housing.
